(19) United States
(12) Patent Application Publication
(10) Pub. No.: US 2010/0311362 A1
(43) Pub. Date: Dec. 9, 2010

(54) Gain compensation device over temperature and method thereof

(76) Inventors: Yi-Bin Lee, Hsinchu City (TW); Po-Sen Tseng, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/478,783

(22) Filed: Jun. 5, 2009

(51) Int. Cl. H04B 1/04; H03F 1/00

(52) U.S. Cl. 455/118; 330/289; 455/127.2

(57) ABSTRACT

A gain compensation device for adjusting gain of an amplifier over temperature is disclosed. The gain of the amplifier is controlled by signals on a gain control end of the amplifier. The gain compensation device comprises a temperature compensation generator, an adder, and a temperature sensor. The temperature compensation generator is for generating an additional gain parameter according to a reference temperature, a current temperature, and a temperature coefficient. The adder comprises a first input end, coupled to the temperature compensation generator for receiving the additional gain parameter, a second input end for receiving a default gain parameter, and an output end coupled to the gain control end of the amplifier for outputting sum of the additional gain parameter and the default gain parameter. The temperature sensor is for providing the current temperature.

### BACKGROUND OF THE INVENTION

1. Field of the Invention

The present invention relates to a gain compensation device over temperature, and more particularly, to a gain compensation device adjusting the gain of an amplifier according to the temperature.

2. Description of the Prior Art

Please refer to FIG. 1. FIG. 1 is a diagram illustrating conventional amplifier AMP₁. The input end of the amplifier AMP₁ receives an input signal S_{IN}, and the output end of the amplifier AMP₁ outputs an output signal S_{OUT}. As shown in FIG. 1, the actual gain G_{ACT} of the amplifier AMP₁ can be set according to the default gain parameter G_{S} through the gain control end of the amplifier AMP₁. Therefore, the input signal S_{IN} can be amplified for generating the output signal S_{OUT}, and the output signal S_{OUT} reaches to the target power level under such setting, wherein the relation between the input signal S_{IN} and the output signal S_{OUT} can be described as in the following equation:

S_{OUT}=S_{IN}×G_{ACT} (1).

Please refer to FIG. 2. FIG. 2 is a diagram illustrating the actual gain G_{ACT} varies as the temperature changes. As shown in FIG. 2, the actual gain G_{ACT} falls as the temperature rises. For example, when the temperature rises by 20° C., the actual gain G_{ACT} of the amplifier AMP₁ falls by 1 dB. Therefore, the actual gain G_{ACT} is different from the default gain parameter G_{S} when the temperature changes. For example, assuming the default gain parameter G_{S} sets the gain of the amplifier AMP₁ to be 10 dB under the temperature 25° C., when the temperature rises up to 30° C., the actual gain of the amplifier AMP₁ falls to 9 dB. In this way, the power of the output signal S_{OUT} cannot be constant since being affected by the variation of the temperature. In other words, the power of the output signal S_{OUT} does not reach to the target power level, and that is unwanted to users.

### SUMMARY OF THE INVENTION

The present invention provides a gain compensation device for adjusting gain of an amplifier. Gain of the amplifier is controlled by signals on a gain control end of the amplifier. The gain compensation device comprises a temperature compensation generator, an adder, and a temperature sensor. The temperature compensation generator is for generating an additional gain parameter according to a reference temperature, a current temperature, and a temperature coefficient. The adder comprises a first input end, coupled to the temperature compensation generator for receiving the additional gain parameter, a second input end for receiving a default gain parameter, and an output end coupled to the gain control end of the amplifier for outputting sum of the additional gain parameter and the default gain parameter. The temperature sensor is for providing the current temperature.

The present invention further provides a RF transmitter. The RF transmitter comprises an RF module, and a temperature compensation amplifying module. The RF module comprises a local oscillator for providing a clock signal, a divider coupled to the clock signal into a first divided clock signal and a second divided clock signal, a first mixer for receiving an I-path base-band signal and the first divided clock signal and accordingly generating an in-phase signal, a second mixer for receiving a Q-path base-band signal and the second divided clock signal and accordingly generating a quadrature-phase signal, a first adder for receiving the in-phase signal and the quadrature-phase signal and accordingly generating an output signal. The first divided clock signal and the second divided clock signal are different by 90 degrees in phase. The temperature compensation amplifying module comprises a gain compensation device, and an amplifier. The gain compensation device comprises a temperature compensation generator for generating an additional gain parameter according to a reference temperature, a current temperature, and a temperature coefficient, a second adder, and a temperature sensor for providing the current temperature. The second adder comprises a first input end, coupled to the temperature compensation generator for receiving the additional gain parameter, a second input end for receiving a default gain parameter, and an output end for outputting sum of the additional gain parameter and the default gain parameter. The amplifier comprises an input end for receiving the output signal from the first adder, a gain control end coupled to the output end of the second adder for receiving the sum of the additional gain parameter and the default gain parameter for the amplifier accordingly controlling gain of the amplifier, and an output end for outputting the received output signal amplified with the controlled gain.

The present invention further provides a method for compensating gain of an amplifier over temperature. The gain of the amplifier is controlled by a default gain parameter received on a gain control end of the amplifier. The method comprises setting a temperature coefficient according to relation between actual gain of the amplifier and temperature, generating an additional gain parameter according to the temperature coefficient, a current temperature, and a reference temperature, and adding the additional gain parameter to the default gain parameter.

The present invention further provides a method for compensating gain of an amplifier over temperature. The gain of the amplifier is controlled by a default gain parameter received on a gain control end of the amplifier. The method comprises setting a temperature coefficient according to relation between actual gain of the amplifier and temperature, setting an offset value according to a target power level of an output signal from the amplifier, generating an additional gain parameter according to the temperature coefficient, the offset value, a current temperature, and a reference temperature, and adding the additional gain parameter to the default gain parameter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating conventional amplifier.

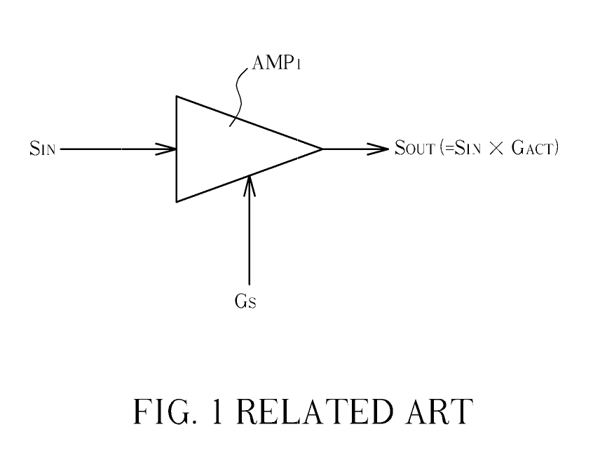

FIG. 2 is a diagram illustrating the actual gain varies as the temperature changes.

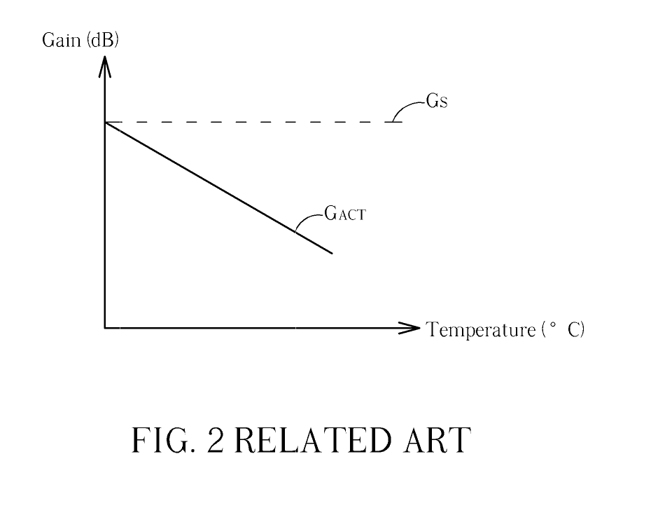

FIG. 3 is a diagram illustrating a RF transmitter of the present invention.

FIG. 4 is a diagram illustrating the actual gain of the amplifier after the gain compensation device of the present invention is utilized.

FIG. 5 is a diagram illustrating one embodiment that the temperature compensation generator generating the additional gain parameter.

FIG. 6 is a diagram illustrating another embodiment that the temperature compensation generator generating the additional gain parameter.

FIG. 7 is a diagram illustrating the temperature sensor of the present invention.

FIG. 8 is a flowchart illustrating a method for compensating the gain of an amplifier over temperature of the present invention.

### DETAILED DESCRIPTION

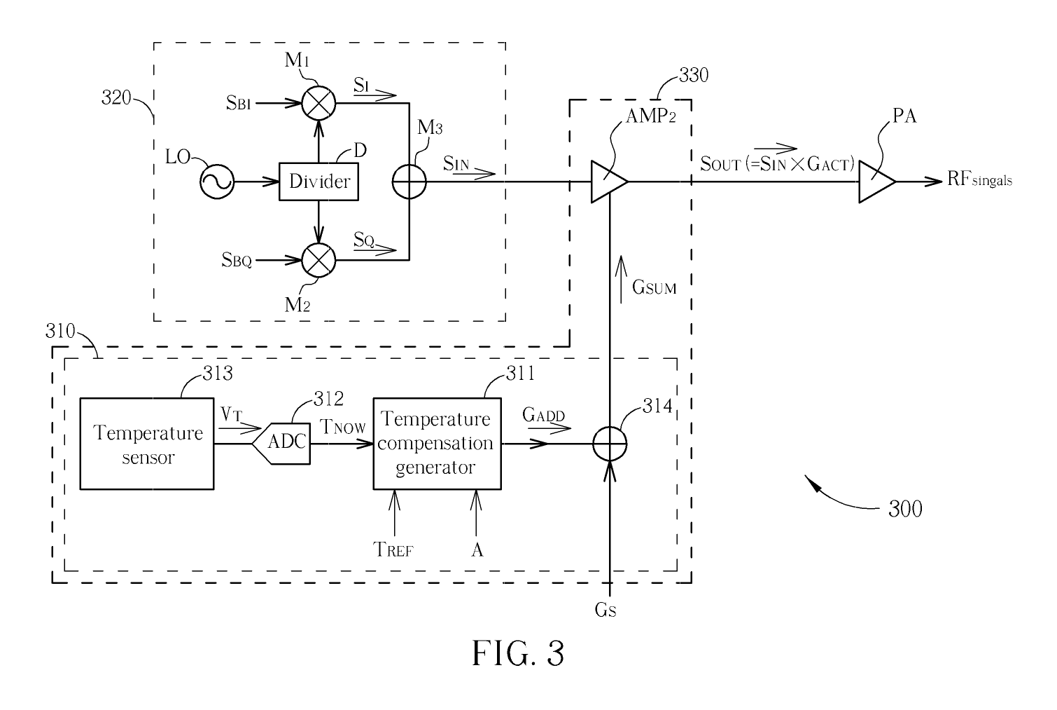

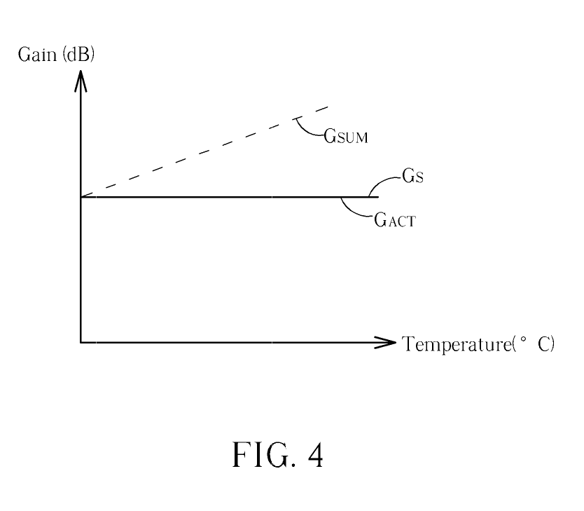

Please refer to FIG. 3 and FIG. 4. FIG. 3 is a diagram illustrating a radio frequency (RF) transmitter 300 of the present invention. FIG. 4 is a diagram illustrating the actual gain G_{ACT} of the amplifier AMP₂ after the gain compensation device 310 is utilized. The RF transmitter 300 comprises a gain compensation device 310, a RF module 320, an amplifier AMP₂, and a power amplifier PA. The power amplifier PA outputs RF signals according to the input signal S_{OUT}. The gain compensation device 310 and the amplifier AMP₂ form a temperature compensation amplifying module 330. The temperature compensation amplifying module 330 amplifies the received signals without temperature effect. In other words, in the temperature compensation amplifying module 330, the amplifier AMP₂ utilizes the gain compensation device 310 to eliminate the temperature effect of RF transmitter 300 so as for the signals outputted from the temperature compensation amplifying module 330 are not affected by the variation of the temperature. More particularly, the gain compensation device 310 provides an additional gain parameter G_{ADD} added to the default gain parameter G_{S} for generating a final gain parameter G_{SUM}. In this way, the gain parameter transmitted to the gain control end of the amplifier AMP₂ becomes (G_{S}+G_{ADD}). The additional gain parameter G_{ADD} rises as the temperature rises, which means the final gain parameter G_{SUM} rises as well. Therefore, as shown in FIG. 4, the actual gain G_{ACT} of the amplifier AMP₂ can be kept as same as the default gain parameter G_{S} without being affected by the change of the temperature. Additionally, in the RF transmitter 300, the power amplifier PA is usually provided with a fixed gain. Therefore, the gain compensation device 310 does not adjust the gain of the power amplifier PA though the actual gain of the power amplifier PA even falls as the temperature rises.

The RF module 320 comprises two mixers M₁ and M₂, an adder M₃, a divider D, and a local oscillator LO. The oscillator LO provides a clock signal to the divider D. The divider D divides the clock signal into a first divided clock signal and a second divided clock signal, which are different from each other by 90 degrees in phase. The mixer M₁ receives the I-path base-band signal S_{BI} and the first divided clock signal from the divider D and mixes the received signals for generating the I (in-phase) signal S_{I}. The mixer M₂ receives the Q-path base-band signal S_{BQ} and the second divided clock signal from the divider D and mixes the received signals for generating the Q (quadrature-phase) signal S_{Q}. The adder M₃ receives the signals S_{I} and S_{Q} and adds them for generating the input signal S_{IN}. The detailed operation of the RF module 320 is well known to those skilled in the art and consequently is omitted.

The gain compensation device 310 comprises a temperature compensation generator 31 1, an Analog/Digital Converter (ADC) 312, a temperature sensor 313, and an adder 314.

The temperature compensation generator 311 receives parameters T_{NOW} (current temperature) and T_{REF} (reference temperature), and a temperature coefficient “A”. The temperature compensation generator 311 decides the value of the additional gain parameter G_{ADD} according to the parameters T_{NOW} and T_{REF}, and the temperature coefficient “A”.

The ADC 312 is coupled between the temperature sensor 313 and the temperature compensation generator 311. The ADC 312 receives voltages transmitted from the temperature sensor 313, and accordingly converts the received voltages into digital domain, and then provides the converted result as the parameter T_{NOW} to the temperature compensation generator 311.

The temperature sensor 313 senses the current temperature and accordingly generates a corresponding voltage V_{T}. The voltage V_{T} can be viewed as a representation of the current temperature for the parameter T_{NOW}. The voltage V_{T} is converted into the digital domain for generating the parameter T_{NOW} by the ADC 312.

The adder 314 comprises a first input end, a second input end, and an output end. The first input end of the adder 314 is coupled to the temperature compensator 311 for receiving the additional gain parameter G_{ADD}. The second input end of the adder 314 receives the default gain parameter G_{S}. The output end of the adder 314 is coupled to the gain control end of the amplifier AMP₂. The adder 314 adds the additional gain parameter G_{ADD} to the default gain parameter G_{S}, and outputs the sum of the parameters G_{ADD} and G_{S}. In other words, the adder 314 outputs the final gain parameter G_{SUM} (G_{ADD}+G_{S}) to the gain control end of the amplifier AMP₂ through the output end of the adder 314.

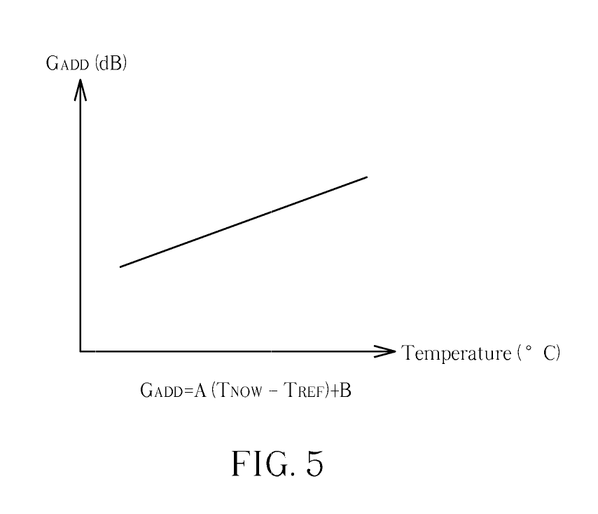

Please refer to FIG. 5. FIG. 5 is a diagram illustrating one embodiment that the temperature compensation generator 311 of the temperature compensation amplifying module 330 generating the additional gain parameter G_{ADD}. As shown in FIG. 5, the relation between the additional gain parameter G_{ADD} and the temperature can be described as the following equation: G_{ADD}=A×(T_{NOW}−T_{REF})+B . . . (2), wherein “A” represents the temperature coefficient (or the slope of the line in the chart), and “B” represents the offset value for calibrating the power of the output signal S_{OUT} to the target power level. The values of “A” and “B” can be constant.

When the temperature compensation amplifying module 330 generator 311 is in the calibration mode, the offset value “B” is decided, and the parameter T_{NOW} is sensed and set as the parameter T_{REF}. Therefore, the additional gain parameter G_{ADD} equals to the offset value “B” according to the equation (2), and the final gain parameter G_{SUM} equals to (G_{S}+B). In this way, the offset value “B” is adjusted while the default gain parameter G_{S} is fixed until the output signal S_{OUT} reaches the target power level, and the offset value “B” is fixed after the output signal S_{OUT} reaches the target power level.

The temperature coefficient “A” can be set according to the gain variation of the RF transmitter 300 over temperature. For example, if the actual gain of the RF transmitter falls by 5 dB when the temperature rises up by 100° C., the temperature coefficient “A” can be set as +1 dB/20° C.

Additionally, the reference temperature T_{REF} can be set as any value as desired, for example, 25° C. More particularly, the temperature compensation amplifying device 300 can be calibrated in any temperature, and the parameter T_{NOW} is then sensed, and is set as the parameter T_{REF}.

In normal operation mode, the temperature compensation generator 311 of the temperature compensating device 300 starts to receive the parameter T_{NOW} for generating the additional gain parameter G_{ADD} according to the equation (2). Consequently, the final gain parameter G_{SUM} (G_{ADD}+G_{S}) rises as the temperature rises because of the disposition of the temperature compensation amplifying module 330, and consequently the actual gain G_{ACT} of the amplifier AMP₂ can be kept as the same value as the default gain parameter G_{S} without affecting by the change of the temperature. That is, the temperature compensation amplifying module 330 achieves to output amplified signals without temperature effect. Therefore, the power level of the output signal S_{OUT} can be kept at the target power level.

However, the temperature compensation generator 311 of the temperature compensation amplifying module 330 does not have to be disposed for keeping the output signal S_{OUT} at the same target power level. In other words, the temperature compensation generator 311 of the temperature compensation amplifying device 300 can adjust the power of the output signal S_{OUT} by adjusting the additional gain parameter G_{ADD} as desired. For example, the temperature compensation generator 311 can adjust the power of the output signal S_{OUT} to be higher/lower than the target power level with respect to the temperature. A user can define his/her own equation for the temperature compensation function.

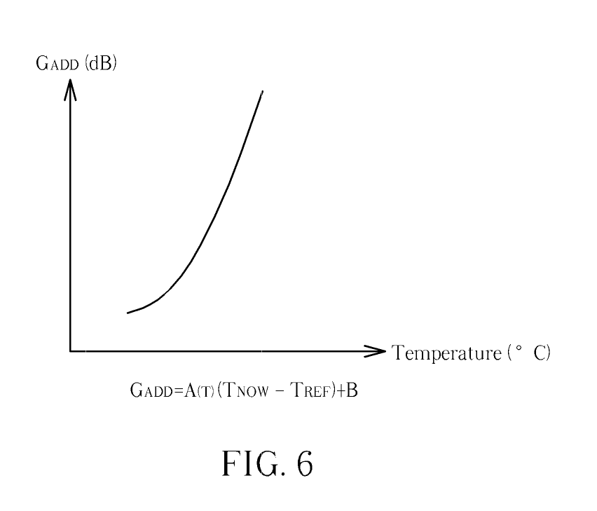

Please refer to FIG. 6. FIG. 6 is a diagram illustrating another embodiment that the temperature compensation generator 311 generating the additional gain parameter G_{ADD}. As shown in FIG. 6, the relation between the additional gain parameter G_{ADD} and the temperature can be described as the following equation: G_{ADD}=A(t)×(T_{NOW}−T_{REF})+B . . . (3), wherein “A(t)” represents the temperature coefficient, and “B” represents the offset value for calibrating the power of the output signal S_{OUT} to the target power level.

The temperature coefficient “A(t)” can be a function of the temperature. For example, the temperature coefficient “A(t)” can be described as the following equation: A(t)=C(ΔT) . . . (3), wherein ΔT represents|T_{Now}−T_{REF}|, and “C” is a constant. In this way, when the difference between the parameters T_{NOW} and T_{REF} goes higher, the coefficient “A(t)” goes higher as well; when the difference between the parameters T_{NOW} and T_{REF} goes lower, the coefficient “A(t)” goes lower as well.

Furthermore, the offset value “B” does not necessarily exist in the equations (2) and (3). A user can omit the calibration mode of the temperature compensation amplifying module 330 and directly use the equations (2) and (3) without the offset value “B” to achieve eliminating the temperature effect to the actual gain of the amplifier AMP₂ for the RF transmitter 300 outputting signals without being affected by the variation of the temperature.

The amplifier AMP₂ mentioned in the present invention can be a Programmable Gain Amplifier (PGA) or a Variable Gain Amplifier (VGA). It is noticeable that if the amplifier AMP₂ is a VGA, a Digital/Analog Converter (DAC) has to be disposed between the output end of temperature compensation generator 311 and first input end of the adder 314. And of course the adder 314 has to be capable of processing analog data. In this way, the additional gain parameter G_{ADD} can be converted into analog domain as need for the VGA.

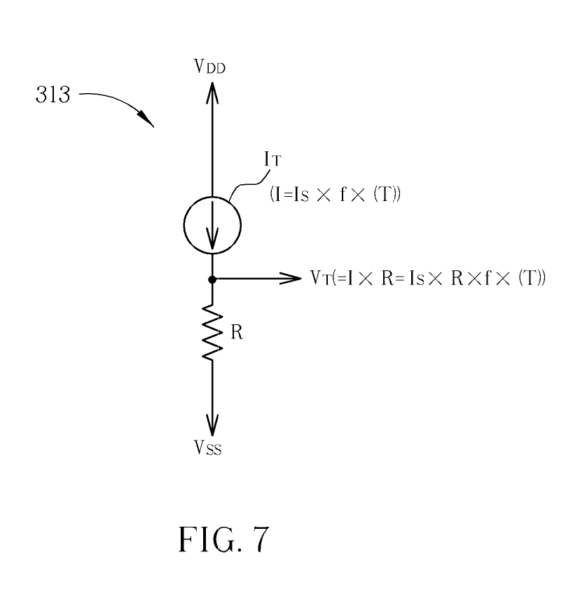

Please refer to FIG. 7. FIG. 7 is a diagram illustrating the temperature sensor 313 of the present invention. As shown in FIG. 7, the temperature sensor 313 can be realized with a Proportional To Ambient Temperature (PTAT) current source I_{T}, and a resistor R. One end of the current source I_{T} is coupled to a biasing source V_{DD}, the other end of the current source I_{T} is coupled to the first end of the resistor R, and the second end of the resistor R is coupled to another biasing source V_{SS}. The temperature sensor 313 outputs a temperature voltage V_{T} to the temperature compensation generator 311 for indicating the currently sensed temperature (T_{NOW}), wherein the temperature voltage V_{T} equals to (I×R).

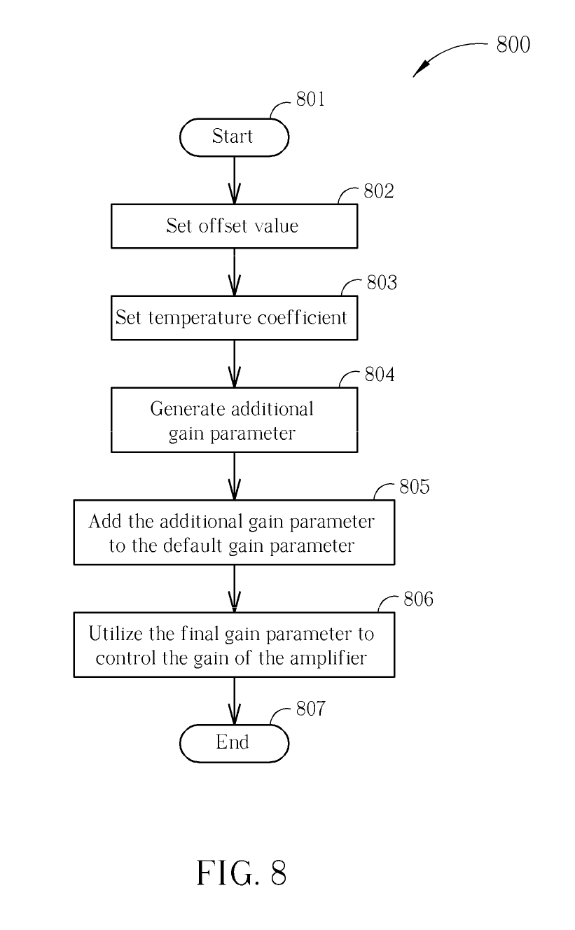

Please refer to FIG. 8. FIG. 8 is a flowchart illustrating a method 800 for compensating the gain of an amplifier for an RF transmitter outputting signals without being affected by the variation of the temperature of the present invention. The steps are described as follows:

Step 801: Start;

Step 802: Set an offset value “B” in order to calibrate the power of the output signal S_{OUT} to the target power level;

Step 803: Set a temperature coefficient “A” according to the relation between the gain of RF transmitter and the temperature;

Step 804: Generate an additional gain parameter G_{ADD} based on the temperature difference between the normal operation mode and the calibration mode;

Step 805: Add the additional gain parameter G_{ADD} to the default gain parameter G_{S} for generating the final gain parameter G_{SUM};

Step 806: Utilize the final gain parameter G_{SUM} to control the gain of the amplifier AMP₂;

Step 807: End.

In step 802, the offset value B is obtained by eliminating the term (A×(T_{NOW}−T_{REF})) from the equation (2). It can be achieved by setting the parameter A to be 0 or (T_{NOW}−T_{REF}) to be 0. Additionally, the temperature sensed in the calibration mode of the temperature compensation amplifying module 330 (the parameter T_{NOW}) is recorded as the parameter T_{REF}.

In step 804, the additional gain parameter G_{ADD} can be generated by the equations (2), (3), or any other equations defined by users. The current temperature T_{NOW} can be sensed by the temperature sensor 313 as described above. Therefore, the actual gain of the amplifier AMP₂ can be controlled with the consideration of temperature change.

To sum up, the present invention provides a temperature compensation amplifying module to compensate the temperature variation so that the RF transmitter utilizes the temperature compensation amplifying module is not affected by temperature variation. Therefore, in the RF transmitter of the present invention, the power of the output signal from the temperature compensation amplifying device of the present invention remains constant without being affected by the change of the temperature, providing great convenience to users.

Those skilled in the art will readily observe that numerous modifications and alterations of the device and method may be made while retaining the teachings of the invention.

What is claimed is:

1. A gain compensation device for adjusting gain of an amplifier over temperature, gain of the amplifier being controlled by signals on a gain control end of the amplifier, the gain compensation device comprising:
a temperature compensation generator for generating an additional gain parameter according to a reference temperature, a current temperature, and a temperature coefficient;
an adder, comprising:
a first input end, coupled to the temperature compensation generator for receiving the additional gain parameter;
a second input end for receiving a default gain parameter; and
an output end, coupled to the gain control end of the amplifier for outputting sum of the additional gain parameter and the default gain parameter; and
a temperature sensor for providing the current temperature.

2. The gain compensation device of claim 1, wherein the temperature compensation generator generates the additional gain parameter according to a following equation:
G_{ADD}=A×(T_{NOW}−T_{REF});
wherein G_{ADD} represents the additional gain parameter, A represents the temperature coefficient, T_{NOW} represents the current temperature, and T_{REF} represents the reference temperature.

3. The gain compensation device of claim 1, wherein the temperature compensation generator generates the additional gain parameter further according to an offset value.

4. The gain compensation device of claim 3, wherein the temperature compensation generator generates the additional gain parameter according to a following equation:
G_{ADD}=A×(T_{NOW}−T_{REF})+B;
wherein G_{ADD} represents the additional gain parameter, A represents the temperature coefficient, B represents the offset value, T_{NOW} represents the current temperature, and T_{REF} represents the reference temperature;
wherein B is calculated to meet a target power level for an output signal outputted from the amplifier when the temperature compensation device is in a calibration mode in order to allow G_{ADD} to be B.

5. The gain compensation device of claim 1, wherein the temperature compensation generator generates the additional gain parameter according to a following equation:
G_{ADD}=A(t)×(T_{NOW}−T_{REF});
wherein G_{ADD} represents the additional gain parameter, A(t) represents the temperature coefficient, T_{NOW} represents the current temperature, and T_{REF} represents the reference temperature;
wherein A(t) is a function of temperature.

6. The gain compensation device of claim 5, wherein A(t)=C×|T_{NOW}−T_{REF}|, and C represents a constant.

7. The gain compensation device of claim 1, wherein the temperature sensor comprising:
a current source with proportional current to the current temperature; and
a resistor coupled to the current source for outputting a voltage as the current temperature.

8. The gain compensation device of claim 7, further comprises an analog/digital converter coupled between the temperature sensor and the temperature compensation generator for converting the voltage into digital domain as the current temperature.

9. An RF transmitter, comprising:
an RF module, comprising:
a local oscillator for providing a clock signal;
a divider coupled to the clock signal into a first divided clock signal and a second divided clock signal;
wherein the first divided clock signal and the second divided clock signal are different by 90 degrees in phase;
a first mixer for receiving an I-path base-band signal and the first divided clock signal and accordingly generating an in-phase signal;
a second mixer for receiving a Q-path base-band signal and the second divided clock signal and accordingly generating a quadrature-phase signal;
a first adder for receiving the in-phase signal and the quadrature-phase signal and accordingly generating an output signal; and
a temperature compensation amplifying module, comprising:
a gain compensation device, comprising:
a temperature compensation generator for generating an additional gain parameter according to a reference temperature, a current temperature, and a temperature coefficient;
a second adder, comprising:
a first input end, coupled to the temperature compensation generator for receiving the additional gain parameter;
a second input end for receiving a default gain parameter; and
an output end for outputting sum of the additional gain parameter and the default gain parameter; and
a temperature sensor for providing the current temperature; and an amplifier, comprising:
an input end for receiving the output signal from the first adder;
a gain control end, coupled to the output end of the second adder, for receiving the sum of the additional gain parameter and the default gain parameter for the amplifier accordingly controlling gain of the amplifier; and
an output end for outputting the received output signal amplified with the controlled gain.

10. The RF transmitter of claim 9, wherein the temperature compensation generator generates the additional gain parameter according to a following equation:
G_{ADD}=A×(T_{NOW}−T_{REF});
wherein G_{ADD} represents the additional gain parameter, A represents the temperature coefficient, T_{NOW} represents the current temperature, and T_{REF} represents the reference temperature.

11. The RF transmitter of claim 9, wherein the temperature compensation generator generates the additional gain parameter further according to an offset value.

12. The RF transmitter of claim 11, wherein the temperature compensation generator generates the additional gain parameter according to a following equation:
G_{ADD}=A×(T_{NOW}−T_{REF})+B;
wherein G_{ADD} represents the additional gain parameter, A represents the temperature coefficient, B represents the offset value, T_{NOW} represents the current temperature, and T_{REF} represents the reference temperature;
wherein B is calculated to meet a target power level for the output signal from the amplifier when the temperature compensation device is in a calibration mode in order to allow G_{ADD} to be B.

13. The RF transmitter of claim 9, wherein the temperature sensor comprising:
a current source with proportional current to the current temperature; and
a resistor coupled to the current source for outputting a voltage as the current temperature.

14. The RF transmitter of claim 13, further comprises an analog/digital converter coupled between the temperature sensor and the temperature compensation generator for converting the voltage into digital domain as the current temperature.

15. The RF transmitter of claim 9, wherein the temperature compensation amplifying module further comprises a power amplifier, the power amplifier comprising:
an input end, coupled to the output end of the amplifier for receiving the amplified output signal from the amplifier; and
an output end for outputting the received signal on the input end of the power amplifier;
wherein the power amplifier amplifies the received signal of the power amplifier with a fixed gain.

16. A method for compensating gain of an amplifier over temperature, the gain of the amplifier being controlled by a default gain parameter received on a gain control end of the amplifier, the method comprising:
setting a temperature coefficient according to relation between actual gain of the amplifier and temperature;
generating an additional gain parameter according to the temperature coefficient, a current temperature, and a reference temperature; and
adding the additional gain parameter to the default gain parameter.

17. The method of claim 16, further comprising sensing the current temperature.

18. The method of claim 17, wherein the additional gain parameter is generated according to a following equation:
G_{ADD}=A×(T_{NOW}−T_{REF});
wherein G_{ADD} represents the additional gain parameter, A represents the temperature coefficient, T_{NOW} represents the current temperature, and T_{REF} represents the reference temperature.

19. A method for compensating gain of an amplifier over temperature, the gain of the amplifier being controlled by a default gain parameter received on a gain control end of the amplifier, the method comprising:
setting a temperature coefficient according to relation between actual gain of the amplifier and temperature;
setting an offset value according to a target power level of an output signal from the amplifier;
generating an additional gain parameter according to the temperature coefficient, the offset value, a current temperature, and a reference temperature; and
adding the additional gain parameter to the default gain parameter.

20. The method of claim 19, further comprising sensing the current temperature.

21. The method of claim 20, wherein the additional gain parameter is generated according to a following equation:
G_{ADD}=A×(T_{NOW}−T_{REF})+B;
wherein G_{ADD} represents the additional gain parameter, A represents the temperature coefficient, B represents the offset value, T_{NOW} represents the current temperature, and T_{REF} represents the reference temperature.
